(19) United States
(12) Patent Application Publication
(10) Pub. No.: US 2010/0140651 A1
(43) Pub. Date: Jun. 10, 2010

(54) DIFFRACTION GRATING LIGHT-EMITTING DIODE

(75) Inventors: Susumu NODA, Kyoto-fu (JP); Takashi ASANO, Kyoto-fu (JP); Masayuki FUJITA, Kyoto-fu (JP); Hitoshi KITAGAWA, Miyagi-ken (JP); Toshihide SUTO, Miyagi-ken (JP)

Correspondence Address: Beyer Law Group LLP, P.O. BOX 1687, Cupertino, CA, 95015-1687, US

(73) Assignee: ALPS ELECTRIC CO., LTD., Tokyo (JP)

(21) Appl. No.: 12/704,325

(22) Filed: Feb. 11, 2010

Related U.S. Application Data
(63) Continuation of application No. PCT/JP2008/002262, filed on Aug. 21, 2008.

(30) Foreign Application Priority Data
Sep. 3, 2007 (JP) 2007-228178

(51) Int. Cl. H01L 33/00

(52) U.S. Cl. 257/98; 257/E33.067

(57) ABSTRACT

The present invention provides a diffraction grating light-emitting diode in which the external quantum efficiency is improved by appropriately setting the period of holes when the holes are two-dimensionally periodically formed. A light-emitting diode is configured by laminating, on a sapphire substrate, an n-type GaN layer, an InGaN/GaN active layer, a p-type GaN layer, and a transparent electrode layer. Further, a large number of holes are two-dimensionally periodically formed in the transparent electrode layer, the p-type GaN layer, the InGaN/GaN active layer, and the n-type GaN layer so as to extend in a direction substantially perpendicular to these layers. Assuming that the non-radiative recombination rate is vₛ, the arrangement period a of the holes satisfies the following expression:

$${v}_{s} {η}_{in}^{( 0 )} / a < \frac{( {F}_{γ} - 1 )}{2 \sqrt{π} K \frac{\sqrt{f}}{( 1 - f )}} {R}_{sp}$$

### CLAIM OF PRIORITY

This application is a Continuation of International Application No. PCT/JP2008/002262 filed on Aug. 21, 2008, which claims benefit of the Japanese Patent Application No. 2007-228178 filed on Sep. 3, 2007, both of which are hereby incorporated by reference.

### BACKGROUND OF THE INVENTION

1. Field of the Invention

The present invention relates to a diffraction grating light-emitting diode.

2. Description of the Related Art

Light emitting diodes (LED) serving as semiconductor light-emitting devices have the characteristics such as low power consumption, long life, small size, high reliability, and the like and are thus widely used in various fields such as display light sources, passenger car tail lamps, signal lamps, backlights of portable devices such as cellular phones and the like, and the like. In recent years, application to passenger car headlamps, illuminating lamps, and the like has been expected, resulting in demand for higher luminance of light-emitting diodes.

A light-emitting diode has a configuration in which a laminate of a p-type semiconductor layer, an active layer, and an n-type semiconductor layer is sandwiched between a pair of electrodes. In such a light-emitting diode, when a voltage is applied between a pair of electrodes, electrons and holes move to the active layer and recombine in the active layer to emit light. The emission efficiency (external quantum efficiency) of the light-emitting diode is determined by the internal quantum efficiency of light emission in the active layer and the efficiency of extraction of emitted light to the outside. Since most of the emitted light stays in the active layer without being extracted to the outside, improvement in the extraction efficiency leads to improvement in the external quantum efficiency, achieving higher luminance.

For example, Japanese Unexamined Patent Application Publication No. 2004-289096 describes a method for improving an external quantum efficiency by forming a photonic crystal structure in a light-emitting diode.

In a photonic crystal, a band structure is formed for energy of light in the crystal due to its periodic structure, and an energy region (wavelength band, photonic band gap (PBG)) in which light propagation is impossible is present. Light having a wavelength within the photonic band gap cannot be propagated in a plane in which a periodic structure is formed but is propagated only in a direction perpendicular to the plane. The photonic band gap is determined by the refractive index of a dielectric material and the period of the periodic structure.

In the light-emitting diode of Japanese Unexamined Patent Application Publication No. 2004-289096, the photonic crystal structure is formed by two-dimensionally periodically forming a large number of holes in a layer structure including a pair of electrodes and a p-type semiconductor layer, an active layer, and an n-type semiconductor layer which are provided between the electrodes so that the holes pass through the three layers. In this configuration, light emitted by recombination of electrons and holes in the active layer cannot be propagated in a plane parallel to each layer but can be extracted only in a direction perpendicular to the layers. Namely, a light-emitting diode having a high extraction efficiency can be realized.

Although a photonic crystal structure is formed by two-dimensionally periodically forming holes in a semiconductor layer, the photonic crystal structure may function as a diffraction grating even if the structure is similar to a photonic crystal. Such a structure is generally referred to as a “diffraction grating structure” and a mechanism of improving the external quantum efficiency of a light-emitting body is different from the above-described photonic crystal structure (hereinafter referred to as the “photonic band gap (PBG) structure).

In the PBG structure, the period of holes is set to be substantially the same as the emission wavelength of a light-emitting body, and the emission wavelength is set within a PBG wavelength region to suppress in-plane emission, thereby enhancing light emission in a direction perpendicular to a plane and thus improving the external quantum efficiency. In addition, the emission wavelength is set at a PBG edge so that the external quantum efficiency is improved by utilizing a high state density at the edge.

In contrast, in the diffraction grating structure, the period of holes is set to be larger than the emission wavelength, and the limit of in-plane wave vector conservation law between the inside and outside of a light-emitting body is replaced by a conservation law including a reciprocal lattice vector of a photonic crystal, thereby relaxing total reflection conditions and thus improving the extraction efficiency, i.e., improving the external quantum efficiency.

When holes are two-dimensionally periodically formed in a light-emitting diode to provide a photonic crystal structure, the structure does not effectively function unless the ratio of the period to the emission wavelength is appropriately set.

Japanese Unexamined Patent Application Publication No. 2004-289096 discloses that the emission efficiency is improved by providing a PBG photonic crystal structure in a light-emitting diode, and when the photonic crystal period is larger than substantially the same value as the emission wavelength, the external quantum efficiency may be decreased.

### SUMMARY OF THE INVENTION

The present invention provides a diffraction grating light-emitting diode in which when holes are two-dimensionally periodically formed, an external quantum efficiency is improved by appropriately setting the period of the holes.

A diffraction grating light-emitting diode according to an embodiment of the present invention includes a first semiconductor layer, an active layer, a second semiconductor layer, a first electrode electrically connected to the first semiconductor layer, and a second electrode electrically connected to the second semiconductor layer, which are laminated in order, wherein a large number of holes are two-dimensionally periodically arranged so as to pass through the active layer and at least one of the first and second semiconductor layers, and assuming that a non-radiative recombination rate is vs, the arrangement period a of the holes is designed to satisfy the following expression:

$${v}_{s} {η}_{in}^{( 0 )} / a < \frac{( {F}_{γ} - 1 )}{2 \sqrt{π} K \frac{\sqrt{f}}{( 1 - f )}} {R}_{sp}$$

(wherein ηᵢₙ⁽⁰⁾ represents an internal quantum efficiency when holes are not provided, K represents a constant determined by an arrangement state of holes, f represents a two-dimensional filling rate of holes, Rₛₚ represents a spontaneous emission rate when holes are provided, F_{γ} represents an increase ratio of light extraction efficiency of a structure provided with holes to that of a structure not provided with holes).

A diffraction grating light-emitting diode according to another embodiment of the present invention includes a first semiconductor layer, an active layer, a second semiconductor layer, a first electrode electrically connected to the first semiconductor layer, and a second electrode electrically connected to the second semiconductor layer, wherein a large number of holes are two-dimensionally periodically arranged so as to pass through at least one of the first and second semiconductor layers and the active layer, and the arrangement period of the holes is set to 1.8 times or more the emission central wavelength of the active layer.

Many defect levels are formed in energy levels of electrons and holes due to the influence of an interface, lattice defects, and the like near a surface of a semiconductor. Therefore, when electrons and holes are recombined near a surface of a semiconductor, electrons or holes occupy the defect levels during the recombination process, thereby emitting heat, not light (surface recombination or non-radiative recombination). When holes are formed in a light-emitting diode, the larger the depth of the holes, the more the diffraction efficiency is improved. However, when the depth of the holes is increased so as to pass through an active layer, the emission efficiency and energy efficiency are decreased due to surface recombination on the side surfaces of the holes. Therefore, usually, relatively shallow holes are provided in a surface of a light-emitting diode so as not to pass through an active layer.

On the other hand, in the present invention, holes are periodically provided in a light-emitting diode to such a depth as to pass through an active layer, and the arrangement period is increased. Therefore, it is possible to decrease the ratio of electrons and holes reaching the side walls of the holes and suppress non-radiative surface recombination while improving the diffraction efficiency. In addition, the total reflection conditions on a surface of the light-emitting diode can be relaxed by increasing the period, resulting in improvement of the light extraction efficiency.

### BRIEF DESCRIPTION OF THE DRAWINGS

FIG. 1 is a graph showing changes in external quantum efficiency due to provision of holes in a GaN-based light-emitting diode;

FIG. 2 is a graph showing a relationship between the period of holes and emission life;

FIG. 3A is a longitudinal sectional view of a light-emitting diode according to an embodiment of the present invention;

FIG. 3B is a cross-sectional view taken along line IIIB-IIIB in FIG. 3A; and

FIG. 4 is a graph showing changes in emission intensity due to provision of holes.

### DESCRIPTION OF THE PREFERRED EMBODIMENTS

A light-emitting diode according to the present invention has a structure in which a laminate of a p-type semiconductor layer, an active layer, and an n-type semiconductor layer is sandwiched between a pair of electrodes. Another layer such as a spacer or the like may be held between the p-type semiconductor and the active layer, the active layer and the n-type semiconductor layer, or the p- or n-type semiconductor layer and the electrode.

In addition, a large number of holes are two-dimensionally periodically provided in a surface of the light-emitting diode. The holes pass through at least the p-type semiconductor layer and/or the n-type semiconductor layer and the active layer, thereby forming a diffraction grating structure in the surface of the light-emitting diode. Each of the holes may pass through all the three layers or terminate in the p-type semiconductor layer and/or the n-type semiconductor layer. Like in conventional diodes, the holes may be arranged in a square lattice or a triangular lattice. In addition, like in conventional diodes, the shape of each hole may be any one of various columnar shapes such as a cylindrical shape and the like.

The diffraction efficiency is improved by increasing the depth of the holes provided in the surface of the light-emitting diode. However, when the holes pass through the active layer, a non-radiative process is increased due to the occurrence of non-radiative recombination centers on the sidewalls of the holes.

However, the ratio of carriers (electrons and holes) reaching the sidewalls of the holes can be decreased by increasing the arrangement period of the holes, thereby suppressing non-radiative recombination. In this case, if the filling rate of the holes (when the holes are arranged in a triangular lattice, the filling rate f=(r/a)2×(2π/√3), and when holes are arranged in a square lattice, the filling rate f=π(r/a)2 wherein a is the arrangement period of holes, and r is the diameter of holes) is maintained constant, the light extraction efficiency due to diffraction can be maintained constant.

In the present invention, the periodic structure of the holes is appropriately designed on the basis of this idea, and a light-emitting diode with a high external quantum efficiency is realized.

Specifically, when the ratio of the non-radiative recombination rate vₛ to the arrangement period a of the holes satisfies the expression (1) below, the external quantum efficiency is increased by the effect of provision of the holes.

$${v}_{s} / a < \frac{{R}_{sp} ( {F}_{γ} {η}^{( 0 ) - 1} - 1 ) - {R}_{sp}^{( 0 )} ( {η}_{in}^{( 0 ) - 1} - 1 )}{2 \sqrt{π} K \frac{\sqrt{f}}{( 1 - f )}} \qquad ( 1 )$$

(wherein ηᵢₙ⁽⁰⁾ represents an internal quantum efficiency when holes are not provided, K represents a constant (when holes are arranged in a triangular lattice, K=1.07, and when holes are arranged in a square lattice, K=1), f represents a filling rate of holes, Rₛₚ⁽⁰⁾ represents a spontaneous emission rate when holes are not provided, Rₛₚ represents a spontaneous emission rate when holes are provided, F_{γ} represents an increase ratio of light extraction efficiency of a structure provided with holes to that of a structure not provided with holes).

Herein, Rₛₚ⁽⁰⁾ and Rₛₚ, ηᵢₙ⁽⁰⁾ and ηᵢₙ, γₑₓ⁽⁰⁾ and γₑₓ, and ηₑₓ⁽⁰⁾ and ηₑₓ, and F_{η} are known to be represented by the expressions (2) to (10) below. The presence and absence of (0) at the upper right of each symbol correspond to the absence and presence of holes, respectively. In addition, “in” and “ex” at the lower right of each symbol correspond to internal emission and external emission, respectively, of the light-emitting diode.

$$\begin{matrix}{R}_{sp}^{( 0 )} = {R}_{ip}^{( 0 )} + {R}_{ex}^{( 0 )} & ( 2 ) \\ {R}_{sp} = {R}_{ip} + {R}_{ex} & ( 3 ) \\ {η}_{in}^{( 0 )} = {R}_{sp}^{( 0 )} / ( {R}_{sp}^{( 0 )} + {R}_{non}^{( 0 )} ) & ( 4 ) \\ {η}_{in} = {R}_{sp} / ( {R}_{sp} + {R}_{non} ) = {R}_{sp} / ( {R}_{sp} + {R}_{non}^{( 0 )} + {R}_{non}^{( hole )} ) & ( 5 ) \\ {γ}_{ex}^{( 0 )} = {R}_{ex}^{( 0 )} / ( {R}_{ip}^{( 0 )} + {R}_{ex}^{( 0 )} ) & ( 6 ) \\ {γ}_{ex} = {R}_{ex} / ( {R}_{ip} + {R}_{ex} ) ≡ {F}_{γ} {γ}_{ex}^{( 0 )} & ( 7 ) \\ {η}_{ex}^{( 0 )} = {R}_{ex}^{( 0 )} / ( {R}_{sp}^{( 0 )} + {R}_{non}^{( 0 )} ) = {γ}_{ex}^{( 0 )} {η}_{in}^{( 0 )} & ( 8 ) \\ {η}_{ex} = {R}_{ex} / ( {R}_{sp} + {R}_{non} ) = {γ}_{ex} {η}_{in} & ( 9 ) \\ {F}_{η} ≡ {η}_{ex} / {η}_{ex}^{( 0 )} = {F}_{γ} \frac{1 + {R}_{non}^{( 0 )} / {R}_{sp}^{( 0 )}}{1 + {R}_{non} / {R}_{sp}} \\ ( \begin{matrix}wherein {R}_{non}^{( hole )} = 2 \sqrt{π} K \frac{\sqrt{{f}_{Vs}}}{( 1 - f ) a} \\ \begin{matrix}\frac{{R}_{non}^{( 0 )}}{{R}_{non}} = \frac{{R}_{non}^{( 0 )}}{{R}_{non}^{( 0 )} + {R}_{non}^{( hole )}} \\ = \frac{1}{1 + {( {R}_{non}^{( 0 )} )}^{- 1} 2 \sqrt{π} K \frac{\sqrt{{f}_{Vs}}}{( 1 - f ) a}}\end{matrix}\end{matrix} ) & ( 10 )\end{matrix}$$

When in the expression (10), F_{γ}>1, the expression (10) is converted to the expression (11) below.

$$a > \frac{2 \sqrt{π} K \frac{\sqrt{{f}_{Vs}}}{( 1 - f )}}{{R}_{sp} ( {F}_{γ} {η}_{in}^{( 0 ) - 1} - 1 ) - {R}_{sp}^{( 0 )} ( {η}_{in}^{( 0 ) - 1} - 1 )} \qquad ( 11 )$$

The expression (11) can be converted to derive the above expression (1).

The minimum value of the right side of the expression (1) is about Rₛₚ×ηᵢₙ⁽⁰⁾⁻¹. Therefore, in a gallium nitride (GaN)-based light-emitting diode with a low internal quantum efficiency, the holes can be formed with an actual period (about 10 μm or less) which permits the function as a diffraction grating so as to satisfy the condition of the expression (1).

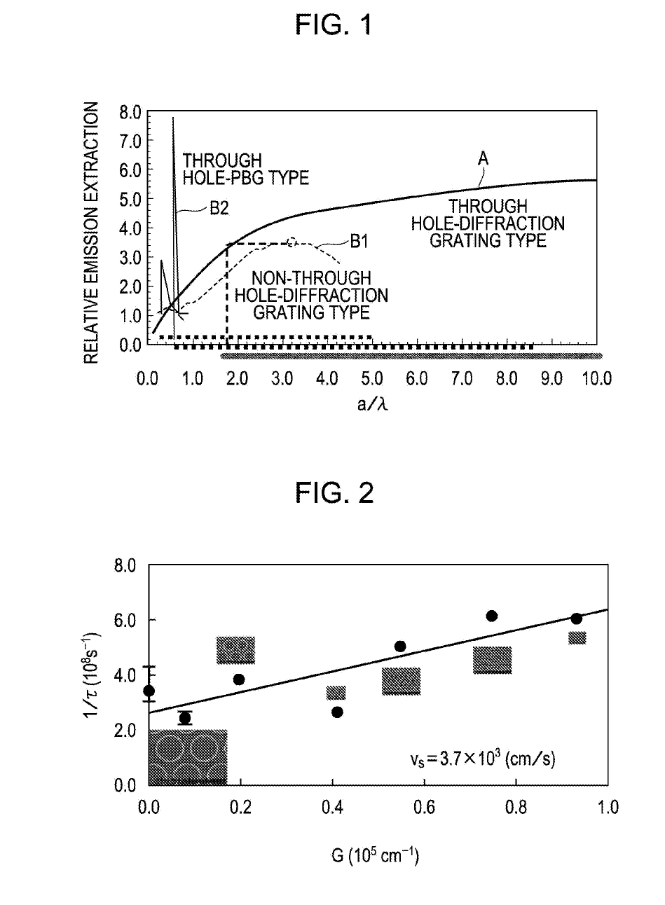

FIG. 1 shows the effect when holes are provided in a GaN-based light-emitting diode. FIG. 1 shows the external quantum efficiency determined by substituting the following value for each parameter.

Rₛₚ⁽⁰⁾(/s)=1.00E+07

Rₛₚ(/s)=1.00E+07

Rₙₒₙ⁽⁰⁾(/s)=4.00E+08

F_{γ}=6.80

ηᵢₙ=0.02(=ηᵢₙ⁽⁰⁾)

f=0.58

vₛ(cm/s)=5.00E+03

K=1.075

In FIG. 1, the ratio (a/λ) of the arrangement period of holes to external emission wavelength is shown on the abscissa, and the external quantum efficiency is shown on the ordinate. In addition, solid line A shows changes in the external quantum efficiency of a diffraction grating light-emitting diode which is a light-emitting diode according to the present invention and which has holes passing through an active layer, and broken line B1 shows changes in the external quantum efficiency of a diffraction grating light-emitting diode which has holes not passing through an active layer. As a reference, the external quantum efficiency of a PBG light-emitting diode (photonic band gap light-emitting diode) is shown by broken line B2.

As seen from FIG. 1, when the ratio (a/λ) of the arrangement period of holes to external emission wavelength on the abscissa is 1.8 or more, a higher external quantum efficiency than the diffraction grating light-emitting diode which has holes not passing through an active layer can be obtained. As described above, in the PBG light-emitting diode, when holes are formed with a period which is substantially the same as the emission wavelength, a high external quantum efficiency can be achieved. However, in the diffraction grating LED according to the present invention, a high external quantum efficiency can be obtained when holes are formed with a period of 1.8 times or more the emission wavelength.

In addition, in a diffraction grating LED, the following expression is generally established.

Rₛₚ≅Rₛₚ⁽⁰⁾

Therefore, the above-described expression (1) can be rewritten as the following expression (12).

$${v}_{s} {η}_{in}^{( 0 )} / a < \frac{( {F}_{γ} - 1 )}{2 \sqrt{π} K \frac{\sqrt{f}}{( 1 - f )}} {R}_{sp} \qquad ( 12 )$$

In particular, in an InGaN-based LED including a green light-emitting material, Vₛ is generally 10³ (cm/s), ηᵢₙ⁽⁰⁾<0.1, and the expression (12) can be satisfied.

FIG. 2 shows an example of results of calculation of a non-radiative recombination rate (surface recombination rate) on the basis of the emission life measured by a time-resolved photoluminescence measurement method using InGaN-based LEDs having a central emission wavelength of 520 nm and holes formed with different periods. In FIG. 2, G (10⁵ cm⁻¹) is shown in the abscissa, and 1/τ(10⁸ s⁻¹) is shown on the ordinate.

In addition, τ represents the emission life, and G is represented by the following expression.

$$G = 2 \sqrt{π} K \frac{\sqrt{f}}{( 1 - f ) a}$$

$$( \begin{matrix}wherein {τ}^{- 1} = {τ}^{- 1} rad + {τ}^{- 1} {nonrad}^{( 0 )} + {τ}^{- 1} {nonrad}^{( hole )} \\ {τ}^{- 1} {nonrad}^{( hole )} = {v}_{s} G\end{matrix} )$$

Herein, assuming that the filling rate f of holes is about 0.58, G is determined by changing the period a of the holes. FIG. 2 indicates that the life increases as the G decreases, i.e., the period a of holes increases. In addition, the gradient of a solid line shown in FIG. 2 corresponds to the non-radiative recombination rate vₛ. According to calculation, vₛ=3.7×10³ (cm/s).

### EMBODIMENT

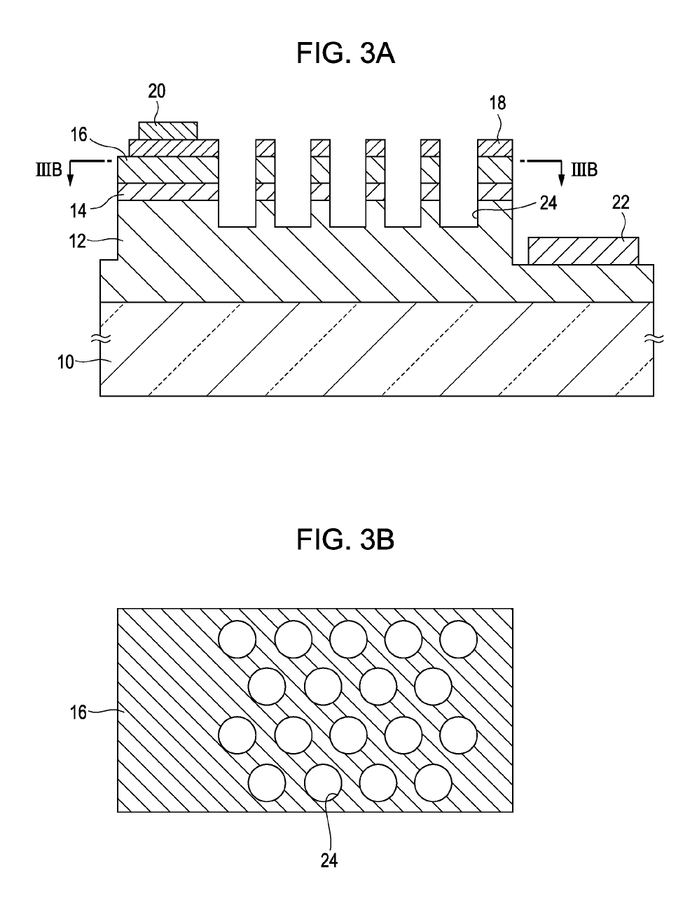

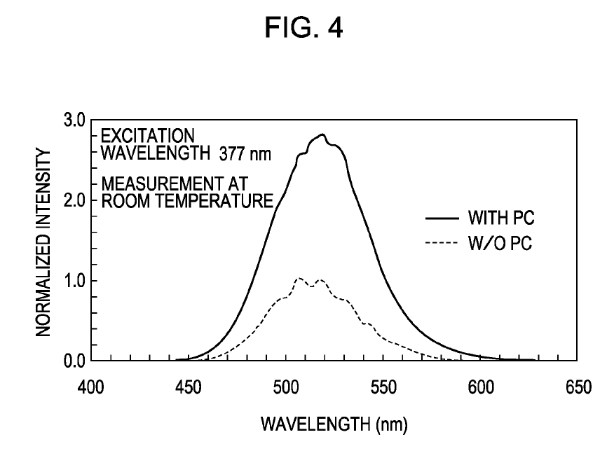

FIGS. 3A and 3B are a longitudinal sectional view and a cross-sectional view, respectively, of a diffraction grating light-emitting diode according to an embodiment of the present invention. In FIGS. 3A and 3B, for convenience of description, the light-emitting diode is exaggerated in length in the thickness direction as compared with an actual light-emitting diode.

The light-emitting diode includes an n-type GaN layer 12, an InGaN/GaN active layer 14, and a p-type GaN layer 16 which are laminated on a sapphire substrate 10. The thickness dimensions of the n-type GaN layer 12, the InGaN/GaN active layer 14, and the p-type GaN layer 16 are set to 2200 nm, 120 nm, and 500 nm, respectively. The InGaN/GaN active layer 14 includes a junction region where electrons of the n-type GaN layer 12 recombine with holes of the p-type GaN layer 16 to emit light. The InGaN/GaN active layer 14 has a multiquantum well structure, for example, a six-layer quantum well structure.

In addition, a transparent electrode layer 18 is laminated on the p-type GaN layer 16, and a p-type electrode 20 is formed on the transparent electrode layer 18. In the light-emitting diode, the n-type GaN layer 12, the InGaN/GaN active layer 14, the p-type GaN layer 16, and the transparent electrode layer 18 are laminated on the sapphire substrate 10 by a usual lamination technique, and then a portion of the laminated structure is removed to expose the n-type GaN layer 12. An n-type electrode 22 is formed on the exposed portion of the n-type GaN layer 12.

Further, a large number of holes 24 are provided in the transparent electrode layer 18, the p-type GaN layer 16, the InGaN/GaN active layer 14, and the n-type GaN layer 12 so as to extend in a direction substantially perpendicular to these layers. The holes 24 are arranged in a triangular lattice within a plane parallel to the p-type semiconductor layer 16, the active layer 14, and the n-type semiconductor layer 12. The holes 24 are not formed in a region where the p-type electrode 20 is formed on the transparent electrode layer 18.

The holes 24 are set to have a diameter of 800 nm and a depth of 850 nm, and the length of each side of the triangular lattice is set to 1 μm. The holes 24 are formed to pass through the transparent electrode layer 18, the p-type GaN layer 16, and the InGaN/GaN active layer 14 and terminate in the n-type GaN layer 12.

In the light-emitting diode configured as described above, when a voltage is applied between the p-type electrode 20 and the n-type electrode 22, holes are injected into the p-type GaN layer 16 from the p-type electrode 20 side, and electrons are injected to the n-type GaN layer 12 from the n-type electrode 22 side. The electrons and holes move to the active layer 14 and recombine to emit light.

FIG. 4 shows the results of an experiment performed for evaluating the external quantum efficiency (light extraction efficiency) due to the holes 24 of the light-emitting diode having the above-described configuration. FIG. 4 indicates that in the light-emitting diode having the holes 24 according to this embodiment, the emission intensity of light at a wavelength of 470 to 570 nm is significantly enhanced as compared with a light-emitting diode not having the holes 24. The central emission wavelength of the light-emitting diode of the embodiment is 520 nm, and thus the external quantum efficiency is improved as compared with a conventional light-emitting diode.

What is claimed is:

1. A diffraction grating light-emitting diode comprising:
a first semiconductor layer, an active layer, a second semiconductor layer, a first electrode electrically connected to the first semiconductor layer and a second electrode electrically connected to the second semiconductor layer, which are laminated in order,
wherein a large number of holes are two-dimensionally periodically arranged so as to pass through the active layer and at least one of the first and second semiconductor layers, and assuming that a non-radiative recombination rate is vₛ, the arrangement period a of the holes is designed to satisfy the following expression:
$${v}_{s} {η}_{in}^{( 0 )} / a < \frac{( {F}_{γ} - 1 )}{2 \sqrt{π} K \frac{\sqrt{f}}{( 1 - f )}} {R}_{sp}$$
(wherein ηᵢₙ⁽⁰⁾ represents an internal quantum efficiency when holes are not provided, K represents a constant determined by an arrangement state of holes, f represents a two-dimensional filling rate of holes, Rₛₚ represents a spontaneous emission rate when holes are provided, F₇ represents an increase ratio of light extraction efficiency of a structure provided with holes to that of a structure not provided with holes).

2. A diffraction grating light-emitting diode comprising:
a first semiconductor layer, an active layer, a second semiconductor layer, a first electrode electrically connected to the first semiconductor layer and a second electrode electrically connected to the second semiconductor layer, which are laminated in order,
wherein a large number of holes are two-dimensionally periodically arranged so as to pass through the active layer and at least one of the first and second semiconductor layers, and the arrangement period of the holes is set to 1.8 times or more the emission central wavelength of the active layer.

3. The diffraction grating light-emitting diode according to claim 1, wherein the emission central wavelength of the active layer is 470 nm to 570 nm.
